(19) United States
(12) Patent Application Publication
(10) Pub. No.: US 2015/0276879 A1
(43) Pub. Date: Oct. 1, 2015

(54) METHOD FOR DIAGNOSING A SELF-BLOWOUT CIRCUIT BREAKER, AND DIAGNOSIS APPARATUS

(71) Applicant: OMICRON ELECTRONICS GMBH, Klaus (AT)

(72) Inventors: Andreas Kurz, Frankfurt (DE); Matthias Hoffacker, Aachen (DE); Armin Schnettler, Aachen (DE); Christian Hille, Aachen (DE)

(73) Assignee: OMICRON ELECTRONICS GMBH, Klaus (AT)

(21) Appl. No.: 14/437,284

(22) PCT Filed: Oct. 28, 2013
(86) PCT No.: PCT/EP2013/072477

§ 371 Date: Apr. 21, 2015

(30) Foreign Application Priority Data
Oct. 29, 2012 (EP) 12007440.6

(51) Int. Cl. G01R 31/333; G01R 31/327

(52) U.S. Cl. CPC G01R 31/3333; G01R 31/3275

(57) ABSTRACT

For diagnosing a self-blast circuit breaker (1), a switching operation of the self-blast circuit breaker (1) is triggered to initiate a pressure wave in a filling gas of the self-blast circuit breaker (1). A pressure as a function of time in at least one region of the self-blast circuit breaker (1) which occurs in response to the switching operation is detected. A state of a burn-off nozzle (11) of the self-blast circuit breaker (1) which is burnt off in a switching operation under load for blowing the filling gas onto a switching arc is determined in dependence on the pressure as a function of time.

### TECHNICAL FIELD

The invention relates to methods and devices for diagnosing circuit breakers. The invention relates in particular to methods and devices, with which the state of a burn-off nozzle of a self-blast circuit breaker can be determined.

### BACKGROUND

Circuit breakers are safety elements which can be used at present in the field of medium and high voltage in alternating voltage networks for interrupting nominal and short-circuit currents. The circuit breaker technology can also be used in direct-current networks. Circuit breakers can, for example, be configured as vacuum circuit breakers or as gas-filled circuit breakers. At the high-voltage, gas-filled circuit breakers are frequently used. The filling gas can, for example, comprise sulfur hexafluoride (SF₆) as insulating and quenching gas.

In most cases, a circuit breaker has two switching contacts which are in contact with one another in the closed state of the circuit breaker. For breaking, the two contacts are moved away from one another and in doing so an arc burning between the contacts is formed. For successful switching-off of the current, it is crucial to quench this arc between the switching contacts. For this purpose, in the case of puffer circuit breakers and in the case of self-blast circuit breakers, quenching and insulating gas is blown onto the arc and cools it. The filling gas, with which the puffer circuit breaker or self-blast circuit breaker is filled, can be composed partially or completely of the quenching gas. For this purpose, this gas must on the one hand be capable of cooling and quenching the arc, and after quenching the arc should prevent an arc-back or restriking between the contacts.

In self-blast circuit breakers, the energy converted in the arc is utilised to build up the gas pressure necessary for blowing onto the arc. The arc between the switching contacts can in this case be guided, during the switching-off operation, in burn-off nozzles made of an insulating material such as polytetrafluoroethylene (PTFE) or another suitable material, which evaporates under the influence of the arc and thus increases an overpressure of the gas. In today's high-voltage networks self-blast circuit breakers with sulfur hexafluoride (SF₆) as insulating medium are widely used.

Manufacturers of circuit breakers prescribe in their maintenance guidelines that the gas compartment of a self-blast circuit breaker is to be opened at specific intervals or after a specific number of switching cycles. The reason for this is so as to inspect the burn-off of contact and nozzle systems. In the past, a reliable method for determining the contact burn-off using the dynamic resistance measurement was established. Nevertheless, customarily the self-blast circuit breakers have to be opened to inspect the nozzle burn-off of the burn-off nozzle made of insulant.

This entails several disadvantages for the operator of the self-blast circuit breaker. The opening of the self-blast circuit breaker is time- and labour-consuming and thus results in high costs. Furthermore, the switchgear in which the self-blast circuit breaker is used has to be at least partially shut down. After opening the housing of a self-blast circuit breaker, there may be an increased susceptibility to faults, which may be due to the risk of incorrect reassembly or the introduction of foreign matter.

A non-invasive and reliable method for determining the nozzle burn-off could delay or even entirely avoid opening of the interrupting chamber. One approach for non-invasive determination of the nozzle burn-off can consist in measuring a frequency response. In this case, the self-blast circuit breaker can be subjected as test object to an electrical or mechanical signal as stimulus and its reaction can be determined in a frequency response analysis (FRA). In this way, for example the burn-off of nozzle material can be determined. However, the implementation of such an approach is complex. The implementation may involve difficulties in particular on use in the field.

A further approach for non-invasive determination of the nozzle burn-off is the temporally resolved measurement of the currents occurring in the network, in order subsequently to calculate the nozzle burn-off occurring at the present current with the aid of simulations. The implementation of this approach would, however, require extensive fitting of the existing protection and control system with suitable units for data acquisition and data storage, resulting in considerable installation complexity and considerable installation costs.

Methods for monitoring circuit breakers, as described, for example, in DE 196 04 203 A1, are limited to observing the drive device or the movable contact of the circuit breaker and do not allow the nozzle burn-off to be inferred.

### SUMMARY

There is therefore still a need for methods and devices with which a nozzle burn-off can be assessed without the interrupting chamber of the self-blast circuit breaker having to be opened. There is in particular a need for such methods and devices which can be simply incorporated in existing maintenance activities and entail only little additional cost and time expenditure.

The object of the invention is to specify methods and devices which provide improvements with regard to the problems described.

A method and a device having the features specified in the independent claims are provided. The dependent claims defined advantageous and preferred embodiments.

In a method of diagnosing a self-blast circuit breaker, a switching operation of the self-blast circuit breaker is triggered to initiate a pressure wave in a filling gas of the self-blast circuit breaker. A pressure as a function of time which occurs in at least one region of the self-blast circuit breaker in response to the switching operation is detected. A state of a burn-off nozzle of the self-blast circuit breaker which is burnt off in a switching operation under load for blowing the filling gas onto a switching arc is determined in dependence on the pressure as a function of time.

In the method, the state of the burn-off nozzle is inferred from the pressure as a function of time. The detection of the pressure profile can take place without the self-blast circuit breaker having to be disassembled and/or the interrupting chamber opened. The pressure build-up required for the measurement can be generated by the compression of a volume in the circuit breaker itself, for example under the action of the drive of the self-blast circuit breaker or in another manner. In this case, the transient pressure profile is influenced by a flow resistance of the nozzle system. The detection of the pressure profile can take place on the assembled self-blast circuit breaker, so that the method can be performed time-efficiently and cost-effectively. The circuit breaker has merely to be isolated for a short period of time in which the self-blast circuit breaker is being maintained. The geometry of the burn-off nozzle influences pressure waves, for example sound waves, which propagate in the filling gas after a switching operation without electric load, so that based on the pressure profile it can be reliably determined whether the burn-off of the burn-off nozzle is so severe that a disassembly of the self-blast circuit breaker is required.

The state of the burn-off nozzle can be determined based on a transient pressure variation which is detected in response to the switching operation in a time interval. The pressure variation varies in dependence on the nozzle burn-off. The existing connection for the gas filling can be utilised as measuring position. It is thus possible to perform the inspection of the nozzle system in the course of standard maintenance directly in situ.

The pressure as a function of time can be detected at a filling port of the self-blast circuit breaker which is spaced from the burn-off nozzle. This filling port is easily accessible also in the assembled state of the self-blast circuit breaker. The measurement can take place without a modification of the circuit breakers being necessary.

The switching operation with which the pressure wave is initiated can be performed without electric load.

The measurement and evaluation can be performed automatically using a diagnostic device, without the self-blast circuit breaker having to be converted for this purpose and brought into a measuring laboratory. The measurement and evaluation can be performed using a compact, mobile diagnostic device. A pressure sensor of the mobile diagnostic device can be removably mounted on the self-blast circuit breaker such that it detects the pressure profile.

In the method, a contact separation of contacts of the self-blast circuit breaker can be detected. The time interval in which the transient pressure variation is evaluated to obtain information about the nozzle burn-off can be set in dependence on a time at which the contact separation takes place. Alternatively or additionally, the data acquisition of the pressure profile can be set in dependence on the time at which the contact separation takes place.

A mechanical drive of the self-blast circuit breaker can be monitored to detect the contact separation. For this purpose, a rotation angle sensor can be mounted on a drive shaft of the self-blast circuit breaker.

In the method, a pressure and a temperature of the filling gas can be detected before the switching operation is triggered. The time interval in which the transient pressure variation is evaluated to obtain information about the nozzle burn-off can be set in dependence on the detected pressure and the detected temperature of the filling gas. In this way, the speed of sound or a variation of the speed of sound in the filling gas can be taken into account. The speed of sound influences the time interval in which pressure variations influenced by the geometry of the burn-off nozzle are detectable at a measuring position, for example at the filling port of the self-blast circuit breaker. The time interval can be set further in dependence on the geometry of the self-blast circuit breaker, in order to take into account the distance between burn-off nozzle and measuring position.

The state of the burn-off nozzle can be determined in dependence on a time integral of the detected transient pressure variation. Since a sign of the pressure variation can depend on the nozzle burn-off, the state of the burn-off nozzle can be reliably determined in this way by simple processing.

The state of the burn-off nozzle can be determined in dependence on a spectral component of the detected pressure as a function of time. The pressure profile which is detected in a time interval after triggering of the switching operation can be subjected to a spectral analysis. For example, a Fourier transformation can be carried out. Alternatively or additionally, the pressure profile can be subjected to a filtering in order to suppress undesired signal components which may be caused, for example, by reflections of sound waves between the side walls of the self-blast circuit breaker.

The determination of the state of the burn-off nozzle can take place automatically and computer-aided. For this purpose, the construction type of the self-blast circuit breaker and/or other information which identifies the self-blast circuit breaker can be input via a user interface of a diagnostic device by a user input. One or more characteristic quantities which depend on the detected pressure profile can be compared with characteristic quantities stored in a database for the construction type, in order to determine the state of the burn-off nozzle. In one configuration, for each construction type, a plurality of time-dependent pressure profile curves can be stored in the database. The pressure profile detected at the self-blast circuit breaker can be compared with the stored pressure profile curves, in order to determine whether the burn-off of the burn-off nozzle has progressed to such an extent that visual inspection or a replacement of the self-blast circuit breaker is required. In a further configuration, a spectral component of the detected pressure profile can be compared with one or more threshold values stored in the database for this construction type. In this way, it can be determined whether the burn-off of the burn-off nozzle has progressed to such an extent that a visual inspection or a replacement of the self-blast circuit breaker is required.

The determined state of the burn-off nozzle can be selected from a group, comprising a first state, which allows operation of the self-blast circuit breaker to be continued, and a second state, which requires a visual inspection of the burn-off nozzle of the self-blast circuit breaker.

The method can be performed using a diagnostic device, in particular a mobile diagnostic device, on the assembled self-blast circuit breaker. The method can be performed non-invasively without opening the interrupting chamber of the self-blast circuit breaker.

According to a further embodiment, a diagnostic device for self-blast circuit breakers is specified. The diagnostic device comprises an interface for receiving pressure data which indicate a pressure as a function of time in at least one region of the self-blast circuit breaker in response to a switching operation of the self-blast circuit breaker. The diagnostic device comprises a control coupled to the interface and configured to determine, in dependence on the pressure data, a state of a blow-off nozzle of the self-blast circuit breaker which is burnt off in a switching operation under load. The diagnostic device can be configured as a mobile diagnostic device.

The effects achieved with the diagnostic device correspond to the effects achieved with the method.

The diagnostic device can comprise a pressure sensor configured to be detachably coupled to the interface. The pressure sensor can have a coupling structure configured for mounting to a filling port of the self-blast circuit breaker.

The diagnostic device can comprise a further sensor or a plurality of further sensors for monitoring a contact separation. For example, the diagnostic device can comprise a rotation angle sensor for detecting a rotation angle of a drive shaft of the self-blast circuit breaker. The diagnostic device can comprise further sensors for detecting the contact separation. For example, the interruption of a weak current by the circuit breaker can be utilised or monitored. The control is coupled to the further sensor and configured to determine the state of the burn-off nozzle in dependence on a pressure variation in a time interval which is a function of a time of the contact separation.

The diagnostic device can comprise a memory, to which the control is coupled. The memory can contain, for a plurality of construction types of self-blast circuit breakers, respective information on a pressure as a function of time after triggering of a switching operation, with which information the control automatically evaluates the pressure profile detected at the self-blast circuit breaker.

The diagnostic device can be configured to perform the method according to an exemplary embodiment. In this case, the control can perform the various evaluating steps of the method in order to determine, with the detected pressure profile, whether the burn-off of the burn-off nozzle has progressed to such an extent that a visual inspection or a replacement of the self-blast circuit breaker is required.

The switching operation which is triggered to initiate a pressure wave in the filling gas can transfer the self-blast circuit breaker from a closed state into an open state. The switching operation can be triggered by the diagnostic device.

Methods and devices for diagnosing self-blast circuit breakers can be used to inspect circuit breakers in medium-voltage networks and high-voltage networks.

### BRIEF DESCRIPTION OF THE FIGURES

The invention is explained below using preferred embodiments with reference to the drawings.

FIG. 1 is a schematic illustration of a self-blast circuit breaker with a mobile diagnostic device according to an exemplary embodiment.

FIG. 2 shows a sectional view of an arcing chamber of the self-blast circuit breaker for explaining a method according to an exemplary embodiment.

FIG. 3 shows an enlarged view of a part of the arcing chamber in a state without nozzle burn-off.

FIG. 4 shows an enlarged view of the part of the arcing chamber in a state with more severe nozzle burn-off.

FIG. 5 shows pressure profiles which are evaluated in methods and mobile diagnostic devices according to exemplary embodiments, in order to determine a state of a burn-off nozzle.

FIG. 6 shows pressure profiles which are evaluated in methods and mobile diagnostic devices according to exemplary embodiments, in order to determine a state of a burn-off nozzle.

FIG. 7 shows pressure profiles which are evaluated in methods and mobile diagnostic devices according to exemplary embodiments, in order to determine a state of a burn-off nozzle.

FIG. 8 shows pressure profiles for different speeds of a contact pin without nozzle burn-off.

FIG. 9 shows pressure profiles for different speeds of a contact pin with more severe nozzle burn-off.

FIG. 10 is a flow diagram of a method according to an exemplary embodiment.

### DETAILED DESCRIPTION OF EXEMPLARY EMBODIMENTS

In the figures, similar or identical reference symbols denote similar or identical elements.

While methods and diagnostic devices according to exemplary embodiments are explained using self-blast circuit breakers with exemplary configurations, the methods and diagnostic devices can be used in self-blast circuit breakers with a large number of other configurations. The illustrated configurations of self-blast circuit breakers are to be understood as merely illustrating operating principles of self-blast circuit breakers. The term “self-blast circuit breaker” is used here synonymously with the terms “self-blast breaker” or “self-blaster” likewise commonly used in the art.

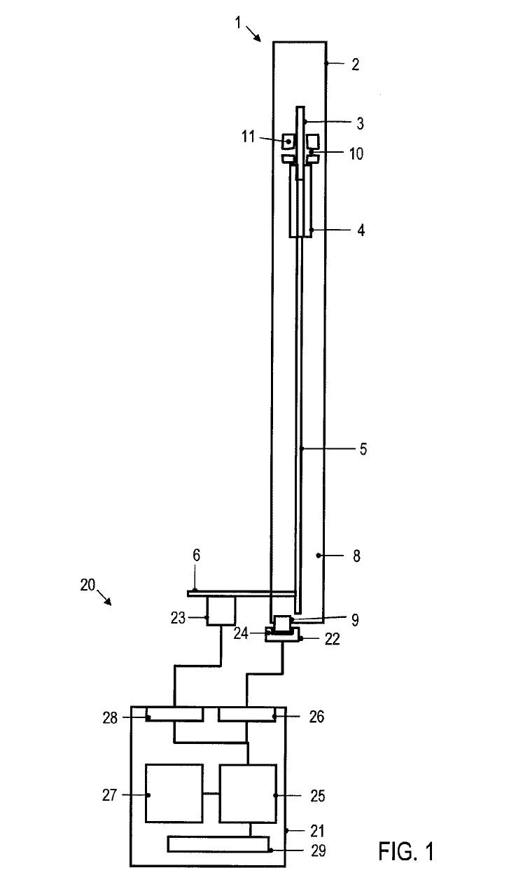

FIG. 1 is a schematic illustration of a self-blast circuit breaker 1 with a mobile diagnostic device 20 according to an exemplary embodiment. The self-blast circuit breaker 1 is a circuit breaker for a medium-voltage network or a high-voltage network. Even though only one self-blast circuit breaker 1 is illustrated, a plurality of self-blast circuit breakers can be combined in a combined arrangement or “battery” of self-blast circuit breakers. In this case, the mobile diagnostic device 20 can automatically perform the described diagnostic device 20 can automatically perform the described diagnostic functions for determining a nozzle burn-off for each of the plurality of self-blast circuit breakers.

The self-blast circuit breaker 1 has a housing 2. A first contact 3 and a second contact 4 are provided in the housing. In the closed state of the self-blast circuit breaker 1, the first contact 3 and the second contact 4 are in contact with one another. In order to transfer the self-blast circuit breaker 1 into the open state, at least one of the contacts is moved. Mechanical components such as a drive rod 5, which is coupled to a motor via a gearing, are provided. A drive shaft 6 can cause a movement of one of the contacts via the drive rod 5, in order to transfer the self-blast circuit breaker 1 into the open state. By way of example, the second contact 4, which can be formed as a finger contact, can be moved together with a burn-off nozzle 11 relative to the first contact 3, which can be a fixed contact pin.

The self-blast circuit breaker 1 is configured as a gas-filled circuit breaker. A filling gas is contained in an interior 8 of the housing 2. By way of example, sulfur hexafluoride (SF₆) can be used as the filling gas, or the filling gas can consist substantially of sulfur hexafluoride. Other insulating and quenching gases can be used. When the in a state in which the self-blast circuit breaker 1 is under electric load, the self-blast circuit breaker 1 is transferred into an open state, the filling gas quenches an arc burning between the first contact 3 and the second contact 4. For this purpose, the filling gas or a mixture of the filling gas and the gas which is produced by nozzle burn-off is blown onto the arc. The filling gas can be blown onto the arc via an opening 10 which is situated in the vicinity of the place at which the arc is burning. For an efficient pressure build-up, the burn-off nozzle 11 is provided in the self-blast circuit breaker 1. The burn-off nozzle 11 is formed from an insulating material or insulant which partially evaporates under the influence of the arc. This process is also called “burning-off” or “burn-off” of the burn-off nozzle 11. The resulting partial pressure can be used for blowing filling gas onto the arc. The burn-off nozzle 11 can be formed, for example, from polytetrafluoroethylene (PTFE) or another suitable insulant.

For maintenance work, the self-blast circuit breaker 1 has a filling port 9, via which the filling gas can be refilled. When a plurality of self-blast circuit breakers are combined in a battery of self-blast circuit breakers, a common filling port 9 can be provided. The filling port 9 can be provided at a housing section extending transversely with respect to a longitudinal axis of the self-blast circuit breaker 1. The filling port 9 can be spaced from an arcing chamber which surrounds the contact region of the first contact 3 and of the second contact 4.

The use of self-blast circuit breakers as circuit breakers has the advantage over conventional puffer circuit breakers that a lower drive can be used. The additional overpressure, produced by the evaporation of the burn-off nozzle 11 and used for blowing the filling gas onto the arc, saves drive energy for the compression of the filling gas. However, it must be ensured that the burn-off nozzle 11 burns off only to such an extent that, in a renewed switching operation, still sufficient material of the burn-off nozzle 11 can evaporate. Moreover, for an efficient pressure build-up in the heating volume, a clogging of the nozzle should occur, which is no longer possible with a nozzle diameter which is too large compared with the flowing current. Thus, it must also be ensured that the burn-off nozzle 11 burns off only to such an extent that an efficient pressure build-up on heating is still possible.

In order to be able to determine the burn-off status of the burn-off nozzle 11 non-invasively, in exemplary embodiments of the invention a transient pressure profile is detected and evaluated when the self-blast circuit breaker 1 without electric load is switched into the open state. In so doing, pressure waves develop in the interior of the self-blast circuit breaker 1, and move through the filling gas at the speed of sound. These pressure waves are influenced by the geometry of the burn-off nozzle 11. By recording the transient pressure profile at a measuring position, for example at the filling port 9, and by subsequent evaluation, the state of the burn-off nozzle can be inferred.

To detect the transient pressure profile which occurs in response to a switching operation at the filling port 9, a mobile diagnostic device 20 is used. As described in more detail below, the mobile diagnostic device 20 is used to detect a transient pressure profile which occurs at a measuring position when the self-blast circuit breaker 1 without electric load is switched into the open state. The transient pressure profile is evaluated in order to determine a state of the burn-off nozzle 11. To determine the state, it is possible to determine, in dependence on the pressure profile, whether the burn-off nozzle 11 is already burnt off to such an extent that an opening of the housing 2 of the self-blast circuit breaker is required to gain access to the interrupting chamber.

The mobile diagnostic device 20 can comprise a pressure sensor 22. The pressure sensor 22 can be attached to the filling port 9, which can be configured as a gas connection. The pressure sensor 22 has mechanical coupling elements 24 which allow a mechanical mounting to the filling port 9. The mechanical coupling elements can be adapted to the geometry of the filling port such that a mechanical mounting to the filling port 9 is possible. The pressure sensor 22 is configured such that, in the state mounted to the filling port 9, it detects a pressure prevailing in the interior of the housing 2 at the filling port 9. The pressure sensor 22 can be configured such that it has a response time which ensures a temporally resolved pressure detection with a high temporal resolution, for example with a temporal resolution of several milliseconds. If the filling port 9 is provided with a nonreturn valve, the pressure sensor 22 has elements which, by opening the nonreturn valve, ensure that the pressure sensor 22 can detect the pressure prevailing in the interior of the housing 2 at the filling port 9. The pressure sensor 22 is coupled to an interface 26 of a mobile measuring device 21. The pressure sensor 22 can be detachably coupled to the interface 26 of the mobile measuring device 21.

The mobile diagnostic device 20 comprises the mobile measuring device 21. The mobile measuring device 21 can be configured as a portable computer which is configured in terms of programming to evaluate the pressure as a function of time prevailing in the interior of the housing 2, in order to determine the state of the burn-off nozzle 21. The mobile measuring device 21 has a control 25 which can comprise one or more processors. The control 25 is coupled to the interface 26 in order to receive from the pressure sensor 22 a signal or data which indicate the pressure profile at the filling port 9. The control 25 processes the data in order to evaluate a pressure profile in a time interval after the switching operation. The time interval can, for example, have a duration of several milliseconds, several tens of milliseconds or several hundreds of milliseconds. The control 25 can perform various processing steps in order to automatically infer the state of the burn-off nozzle 11 from the detected pressure profile. For this purpose, the control 25 can, for example, integrate a pressure variation in a time interval or determine spectral components of the pressure profile by calculation. Alternatively or additionally, the control 25 can compare the pressure profile as function of time with one or more reference curves. Depending on the evaluation of the pressure profile, the control 25 can automatically determine whether the burn-off of the burn-off nozzle has progressed to such an extent that the interrupting chamber of the self-blast circuit breaker 1 has to be opened in order to subject the burn-off nozzle 11 to a visual inspection.

The mobile measuring device 21 can have a user interface 29. A result of the evaluation of the pressure profile can be output by the control 25 via the user interface 29 and/or stored in a memory 27 of the mobile measuring device 21.

In order to take account of the fact that self-blast circuit breakers exist with different geometry and configuration, the user can input information via the user interface 29 which relates to the self-blast circuit breaker 1 and which is used by the control 25 in the automatic evaluation of the detected pressure profile. For example, the mobile measuring device 21 can be configured such that the user can specify a model designation of the self-blast circuit breaker via the user interface 29, for example by selecting from a predetermined group of models. The memory 27 contains for the different models or construction types respective reference data with which the control 25 can evaluate the detected pressure profile to determine the state of the burn-off nozzle 11. The reference data stored in the memory 27 can have different formats depending on the processing of the detected pressure profile which is performed by the control 25. If, for example, the control 25 determines a single characteristic quantity from the detected pressure profile by temporal integration or spectral analysis of the pressure profile, there can be stored in the memory 27 for each of a plurality of construction types a respective threshold value. Based on a comparison of the characteristic quantity determined from the pressure profile with the threshold value, the control 25 can automatically determine whether the burn-off of the burn-off nozzle 11 has progressed to such an extent that the housing 2 of the self-blast circuit breaker has to be opened. If the control 25 determines from the detected pressure profile, for example by spectral analysis of the pressure profile, a plurality of characteristic quantities which can correspond to the spectral components, there can be stored in the memory 27 for each of a plurality of construction types a respective plurality of threshold values with which the control 25 can evaluate the detected pressure profile. In a further configuration, there can be stored in the memory 27 for each of a plurality of construction types of self-blast circuit breakers a respective plurality of characteristic transient pressure profiles. The control 25 can compare the detected pressure profile in the time domain with the characteristic transient pressure profiles stored in the memory 27, in order to automatically determine whether the burn-off of the burn-off nozzle 11 has progressed to such an extent that the housing 2 of the self-blast circuit breaker has to be opened.

Alternatively or additionally, the mobile measuring device 21 can also archive transient pressure profiles which are detected after a switching operation without electric load in a plurality of maintenance procedures on the self-blast circuit breaker which has just been inspected. An evaluation of the detected pressure profile for determining the nozzle burn-off can take place based on a comparison with pressure profiles which have been detected in earlier maintenance procedures on the self-blast circuit breaker 1. Based on the variation of the detected pressure profile, the control 25 can infer an increasing burn-off of the burn-off nozzle 11 and automatically determine whether the interrupting chamber of the self-blast circuit breaker 1 has to be opened. In such a diagnosis which is based on the historical data of the respective self-blast circuit breaker 1, the user can input via the user interface 29 information which uniquely identifies the self-blast circuit breaker 1.

If a plurality of self-blast circuit breakers are combined in a battery having a common filling port, the control 25 can perform the evaluation separately for each of the plurality of self-blast circuit breakers. The pressure variation prevailing at the filling port in the interior of the housing depends generally on which of the plurality of self-blast circuit breakers is switched into the open state, since the pressure waves in the filling gas have to travel over different paths from the nozzle region of the corresponding self-blast circuit breaker to the filling port. Accordingly, there can be stored in the memory 27 for each of the plurality of self-blast circuit breakers of a battery of self-blast circuit breakers data which allows an evaluation of the pressure profile detected in response to a switching operation of the corresponding self-blast circuit breaker at the filling port, in order to determine the state of the burn-off nozzle of the corresponding self-blast circuit breaker.

The mobile diagnostic device 20 can have further components. The beginning and end of a time interval, in which the geometry of the burn-off nozzle 11 can be inferred from the transient pressure profile in the interior of the housing 2, depend on when the switching operation is triggered. To determine this time, a further sensor 23 or a plurality of further sensors can be provided. The further sensor 23 can monitor a drive of the self-blast circuit breaker and/or measure an electrical resistance, voltage drop or current between the contacts 3 and 4. The further sensor 23 can, for example, be configured as a rotation angle sensor which monitors a rotation angle of the drive shaft 6. The further sensor 23 can be detachably coupled to a further interface 28 of the mobile measuring device 21. The control 25 can use the data detected by the further sensor 23 to determine the time of a contact separation of the contacts 3 and 4 of the self-blast circuit breaker. The control 25 can use this time to begin a recording of a pressure profile and/or to select, from a pressure profile detected by the pressure sensor 22 over a longer period of time, a part which represents the transient pressure profile after the switching operation and provides information about the burn-off of the burn-off nozzle 11.

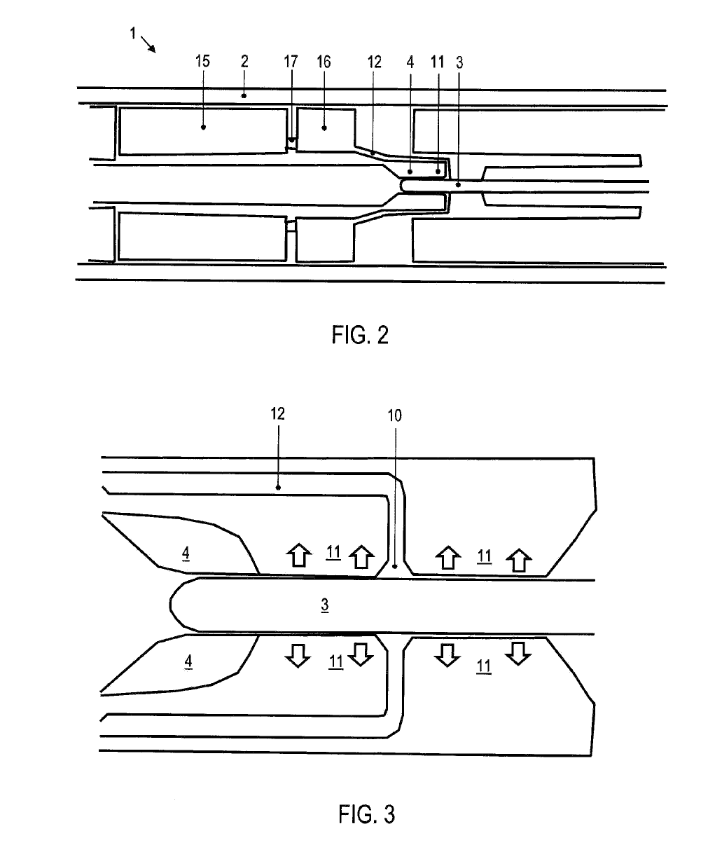

FIG. 2-4 illustrate the construction of an arcing chamber of a self-blast circuit breaker, in which the method and the mobile diagnostic device according to exemplary embodiments can be used. FIG. 2-4 show cross-sectional views along the longitudinal axis of the self-blast circuit breaker.

In the interior of the housing 2 of the self-blast circuit breaker 1, a compression volume 15 and a heating volume 16 are provided. The compression volume 15 and the heating volume 16 can be connected by a nonreturn valve 17. The compression volume 15 and the heating volume 16 are gas compartments formed in the interior of the housing 2. The contacts of the switch comprise a finger contact 4 and a contact pin 3. Other configurations of the contacts can be used. The burn-off nozzle 11, which is composed of an insulant, is connected to the finger contact 4. The heating volume 16 is in a fluid connection, via a passage 12, with an opening 10, at which, for example in the case of a short-circuit breaking, the arc can be subjected to a flow of the filling gas. Depending on the design of the switch, a plurality of such passages 12 may also be provided.

When the self-blast circuit breaker 1 is switched into the open state, the switching action causes a volume reduction of the compression volume 15. The pressure in the compression volume 15 and heating volume 16 rises. When the nozzle region of the burn-off nozzle 11 is freed by the relative movement between the finger contact 4 and the contact pin 3, a flow begins in which the gas flows into the nozzle region via the passage 12. By the end of the switching operation, a stagnation point forms at the place where the gas flow flows out of the heating volume 16 via the passage 12 into the nozzle region. Also in spaced regions of gas volume in the interior 8 of the self-blast circuit breaker 1, the resulting pressure waves in the filling gas lead to a transient pressure variation. This can be monitored at a measuring position, for example at the filling port 9.

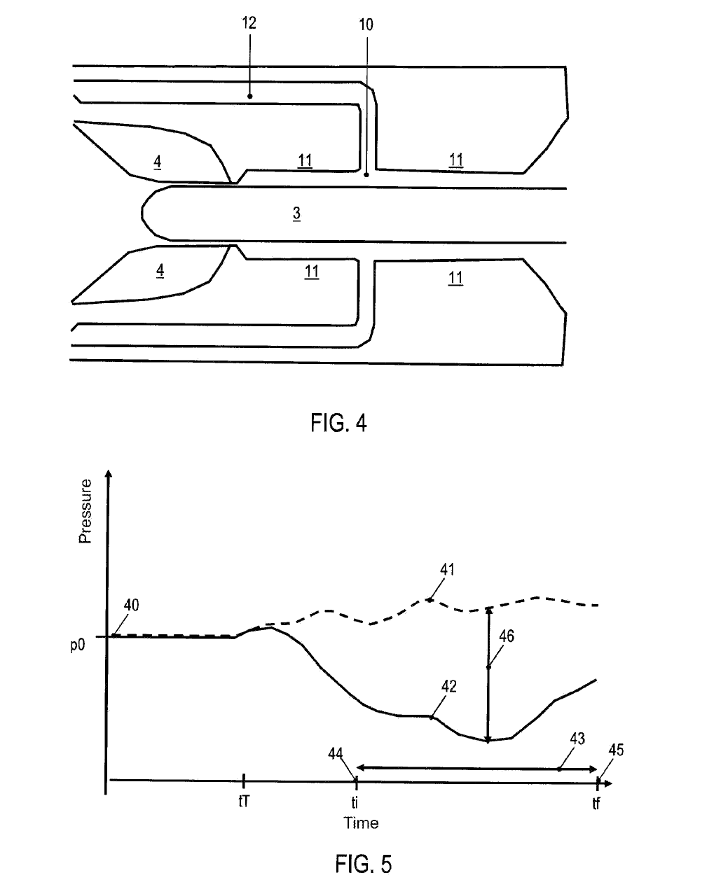

FIG. 3 and FIG. 4 show an enlarged cross-sectional view of the nozzle region which is formed by the burn-off nozzle 11. When the self-blast circuit breaker 1 under electric load is switched into the open state, an arc burning between the contacts 3 and 4 causes the burn-off nozzle 11 to evaporate at its radially inner region in order to support the pressure build-up for blowing the filling gas onto the arc. Owing to the burning-off of the burn-off nozzle 11, the nozzle geometry widens radially, as illustrated schematically in FIG. 3 by arrows. FIG. 4 shows the nozzle region after a plurality of switching operations under load. The changing nozzle geometry influences the propagation of sound waves or other pressure waves in the filling gas during a switching operation. The different pressure profiles, depending on the state of the burn-off nozzle 11, which can be observed for example at the filling port 9 in the gas volume, allow the determination of the state of the burn-off nozzle from the detected pressure profile.

FIG. 5 shows schematically pressure profiles which occur at a measuring position of the self-blast circuit breaker 1 after a switching operation into the open state without load. In this case, the pressure profile 41 illustrated by a dashed line corresponds to a system without nozzle burn-off. The pressure profile 42 illustrated by a continuous line corresponds to a system in which the burn-off nozzle 11 is radially burnt off to such an extent as is the case in typical self-blast circuit breakers after approximately eight short-circuit breaking instances.

FIG. 5 shows the transient pressure profile which results at a measuring position spaced from the nozzle region of the self-blast circuit breaker. The measuring position can, for example, be arranged at the axial end of the self-blast circuit breaker. The transient behaviour over a period of time totaling 50 ms is illustrated. The illustrated pressure profiles were determined for a typical filling pressure and a typical contact speed in the switching operation.

The detected pressure profile at the measuring position, for example at the filling port 9, exhibits substantial differences depending on the extent to which the nozzle is burnt off. At the beginning of the switching action, the transient pressure profile 41 in a self-blast circuit breaker without nozzle burn-off and the transient pressure profile 42 in a self-blast circuit breaker with nozzle burn-off exhibit the same profile as a function of time. The pressure profile 41 in the self-blast circuit breaker without nozzle burn-off rises subsequently and settles around an increased value. The pressure profile 42 in the self-blast circuit breaker with nozzle burn-off exhibits a completely different behaviour. After reaching a first local maximum, the pressure falls below the initial pressure, which corresponds to the filling pressure. The pressure difference between the two pressure profiles 41 and 42 in the present example reaches a value, illustrated at 46, which occurs after a time of several milliseconds or several tens of milliseconds, for example after approximately 40 ms. Only subsequently does the pressure profile 42 rise in the self-blast circuit breaker with nozzle burn-off and approach the pressure profile 41 in the self-blast circuit breaker without nozzle burn-off.

The different pressure profiles can be automatically detected in methods and mobile diagnostic devices according to exemplary embodiments. For this purpose, for example, the pressure profile, detected in a time interval 43 after the beginning of the switching action, is analysed. Various processing steps can be performed for this purpose, such as temporal integration of the pressure variation with respect to the filling pressure, spectral analysis in the interval 43 and/or direct comparison of the pressure profiles 41 and 42 which are detected in the time interval 43. A start time 44 and an end time 45 of the time interval can be set in dependence on the time tT at which the contact separation takes place. The electrode burn-off of the contacts 3 and 4 of the self-blast circuit breaker can be taken into account here. Alternatively or additionally, the time interval 43 can also be set in dependence on the speed of sound in the filling gas and in dependence on the geometry of the self-blast circuit breaker 1. In this way, the propagation time of the pressure waves from the nozzle region to the measuring position, i.e. for example to the filling port 9, can be taken into account.

Different transient pressure profiles in dependence on the state of the burn-off nozzle can also be observed in variations in the parameters of the self-blast circuit breaker, for example for different filling pressures, different contact speeds or different electrode burn-off. The methods and devices according to exemplary embodiments can thus also be used while taking into account boundary conditions which change on use in the field, such as filling pressure fluctuations, electrode burn-off or changing contact speeds. While these parameters only weakly influence the pressure profile at the measuring position, for example at the filling port, resulting in response to a switching operation without electric load, the transient pressure profile exhibits substantial differences in dependence on the nozzle burn-off.

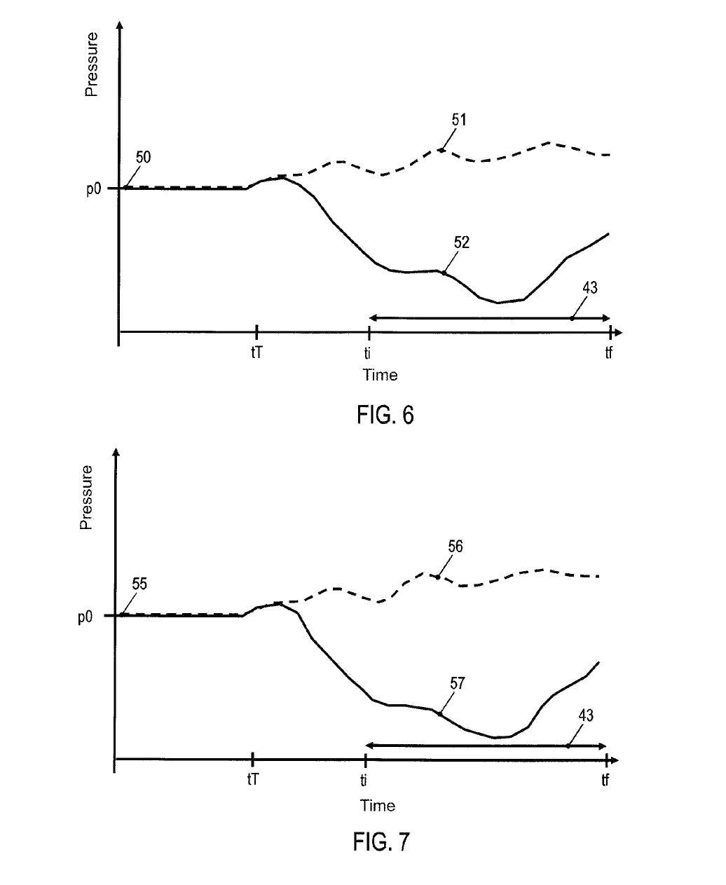

FIG. 6 and FIG. 7 shows pressure profiles which occur at a measuring position of the self-blast circuit breaker 1 after a switching operation into the open state without load. In this case, the pressure profile 51 and 56, respectively, illustrated by a dashed line corresponds to a system without nozzle burn-off. The pressure profile 52 and 57, respectively, illustrated by a continuous line corresponds to a system in which the burn-off nozzle 11 is radially burnt off to such an extent as is the case in typical self-blast circuit breakers after approximately eight short-circuit breaking instances. The transient behaviour over a period of time totaling 50 ms is illustrated. The curves were determined for a typical contact speed in the switching operation.

In contrast to the pressure profiles illustrated in FIG. 5, the pressure profiles for other filling pressures, illustrated in FIG. 6 and FIG. 7, are determined. The pressure profile 51 illustrated in FIG. 6 for a self-blast circuit breaker without nozzle burn-off and the pressure profile 52 for a self-blast circuit breaker with nozzle widening were determined for a filling pressure 50 which is greater than the filling pressure 40 in FIG. 4. The pressure profile 56 illustrated in FIG. 7 for a self-blast circuit breaker without nozzle burn-off and the pressure profile 57 for a self-blast circuit breaker with nozzle widening were determined for a filling pressure 55 which is greater than the filling pressure 40 in FIG. 4 and than the filling pressure 50 in FIG. 5.

The substantial differences in the pressure profile in dependence on the state of the burn-off nozzle, which are explained with reference to FIG. 5, can be observed for various filling pressures. The detected pressure profile for a system without or with low nozzle burn-off can be reliably differentiated from the detected pressure profile for a system with more severe nozzle burn-off, for example after a plurality of short-circuit breaking instances. A non-invasive determination of the nozzle burn-off based on the detected pressure profile is robust to variations of the filling pressure.

A change of the contact speed, with which the contacts 3 and 4 of the self-blast circuit breaker in a switching operation are moved relative to one another, can influence the behaviour of the transient pressure profile at the measuring position. The characteristic differences, which exist in the transient pressure profile in response to a switching operation between a self-blast circuit breaker without nozzle burn-off and a self-blast circuit breaker with nozzle burn-off, can be observed for different contact speeds.

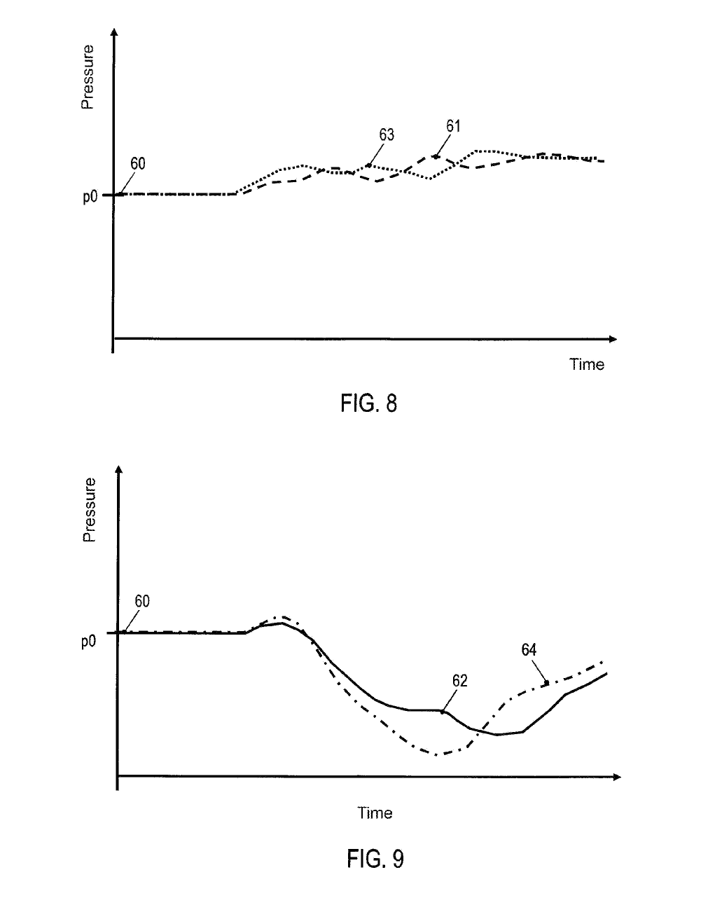

FIG. 8 and FIG. 9 illustrate the transient pressure profile at the measuring position when the switching action takes place with different contact speeds. The transient behaviour over a period of time totaling 50 ms is illustrated. The pressure profiles were determined for a typical filling pressure 60.

FIG. 8 shows the transient pressure profile at the measuring position for a self-blast circuit breaker without nozzle burn-off. The pressure profile 61, illustrated by a dashed line, at the measuring position was determined for a typical contact speed in the switching operation. The pressure profile 63, illustrated by a dotted line, at the measuring position was determined for a contact speed which is approximately 40% greater than the contact speed in the pressure profile 61.

FIG. 9 shows the transient pressure profile at the measuring position for a self-blast circuit breaker with nozzle burn-off which has resulted in a widening of the nozzle diameter by 4 mm. The pressure profile 62, illustrated by a continuous line, at the measuring position was determined for a typical contact speed in the switching operation. The pressure profile 64, illustrated by a dash-dot line, at the measuring position was determined for a contact speed which is approximately 40% greater than the contact speed in the pressure profile 62.

The contact speed influences the pressure as a function of time detected at the measuring position. In the case of a self-blast circuit breaker without nozzle burn-off, the pressure profile 61 for a lower contact speed initially exhibits a less steep rise than the pressure profile 63 for a higher contact speed. In both cases, the pressure profile exhibits oscillations and finally levels out at an increased value. In the case of a self-blast circuit breaker with nozzle burn-off, the pressure profile 64 exhibits for a higher contact speed initially a steeper rise than the pressure profile 62 determined for the lower contact speed. The subsequent pressure drop in the pressure profile 64 for the higher contact speed is also more pronounced and takes place more quickly than in the pressure profile 62 for the lower contact speed.

Despite the influence which the contact speed of the self-blast circuit breaker has on the transient pressure profile at the measuring position, the characteristic differences between the transient pressure profile in the case of a self-blast circuit breaker without or with low nozzle burn-off and a self-blast circuit breaker with more severe nozzle burn-off remain. A non-invasive determination of the nozzle burn-off based on the detected pressure profile can be reliably performed also in the case of self-blast circuit breakers with different contact speeds.

Further investigations on self-blast circuit breakers show that an electrode burn-off of the first contact 3 and/or of the second contact 4 of the self-blast circuit breaker 1 only weakly influences the pressure profiles detected at the measuring position. The characteristic differences which exist in the transient pressure profile in response to a switching operation between a self-blast circuit breaker without nozzle burn-off and a self-blast circuit breaker with nozzle burn-off can even be observed when the contacts 3 and 4 of the self-blast circuit breaker 1 are altered by nozzle burn-off. A non-invasive determination of the nozzle burn-off based on the detected pressure profile can be reliably performed also in the case of self-blast circuit breakers which exhibit different electrode burn-off.

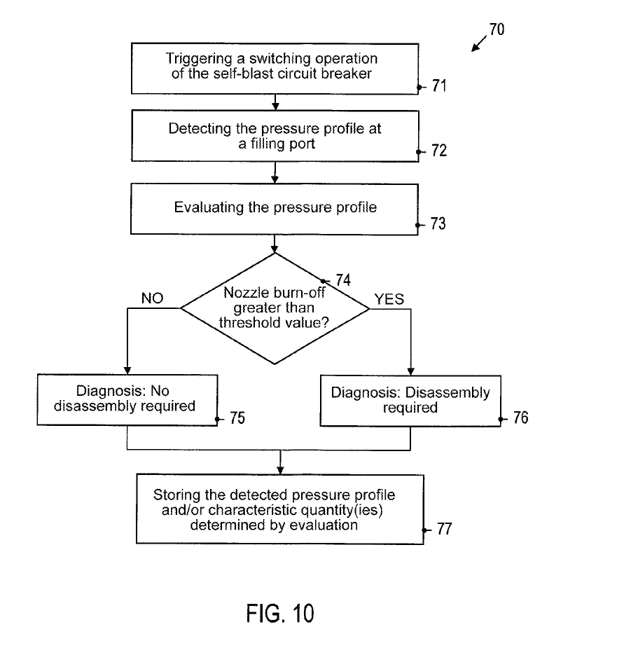

FIG. 10 is flow diagram of a method 70 according to an exemplary embodiment. The method can be automatically performed by the mobile diagnostic device 20 which was explained with reference to FIG. 1. The method 70 can be performed during maintenance of the assembled self-blast circuit breaker. For this purpose, the mobile diagnostic device 20 can be installed on the self-blast circuit breaker after the self-blast circuit breaker has been isolated.

At 71 a switching operation of the self-blast circuit breaker without electric load is triggered. In the switching operation, the self-blast circuit breaker can be switched from the closed state into the open state.

At 72 a time-dependent pressure profile which results in response to the switching operation is detected at a measuring position. The measuring position can be a filling port for filling the self-blast circuit breaker with filling gas.

At 73 the detected pressure profile is evaluated. For this purpose, the pressure profile detected in the time domain can be compared with at least one reference curve which is stored in the mobile diagnostic device 20, in order to determine the state of the burn-off nozzle. Alternatively or additionally, the pressure profile detected in a time interval after triggering of the switching operation can be subjected to various data processing procedures in order to determine the state of the burn-off nozzle. For example, a pressure variation with respect to a filling pressure in the time interval can be integrated over time to reliably determine whether the pressure at the measuring position increases or decreases during the time interval. Alternatively or additionally, a frequency spectrum of the pressure profile, which exhibits the pressure profile during the time interval, can be determined. The start time and end time of the time interval for which the transient pressure profile is evaluated can be set in dependence on the time of the contact separation of the self-blast circuit breaker in the switching operation, which is triggered at 71. The circuit breaker geometry and speed of sound in the filling gas can be taken into account in the setting of the time interval. The start time of the relevant time interval in which the detected pressure can reliably provide information about the nozzle burn-off can be determined from the time of the contact separation and the propagation time of the pressure wave, which is in dependence on the speed of sound and the length of path between nozzle region and measuring position. The transient pressure profile at the measuring position, which can provide information about the nozzle burn-off, can die out in a time of several tens of milliseconds to several seconds. Accordingly, the time interval for which the transient pressure profile is evaluated can have a duration of less than one second, in particular of less than 500 ms, in particular of less than 100 ms. An observation and evaluation of the pressure profile can also take place over longer time intervals. As was described with reference to FIG. 5-9, however, the state of the burn-off nozzle can be inferred already from the transient behaviour which can be observed, for example, in a period of time of 50 ms.

At 74-76 it can be determined, in dependence on the evaluation of the pressure profile at 73, what state the burn-off nozzle is in. In this case, as illustrated for the method 70, it can be determined whether a disassembly of the self-blast circuit breaker is required. At 74 it can be determined whether the nozzle burn-off is greater than a threshold value. For this purpose, a characteristic quantity determined at 73 from the transient pressure profile can be compared with a threshold value.

If at 74 it is determined that the nozzle burn-off has not yet progressed to such an extent that an interrupting chamber of the self-blast circuit breaker has to be opened for a visual inspection of the burn-off nozzle, a corresponding diagnosis result can be output at 75. For example, information that no disassembly of the self-blast circuit breaker is required can be output via a user interface.

If at 74 it is determined that the nozzle burn-off has progressed to such an extent that an interrupting chamber of the self-blast circuit breaker has to be opened for a visual inspection of the burn-off nozzle, a corresponding diagnosis result can be output at 76. For example, information that the self-blast circuit breaker has to be disassembled can be output via a user interface.

At 77 a logging of the pressure profile measurement by the mobile diagnostic device can take place. For this purpose, the detected transient pressure profile at the measuring position after triggering the switching operation and/or a characteristic quantity determined from the transient pressure profile can be stored in a memory of the mobile diagnostic device. The pressure profile measurement and/or the associated log can be archived.

The mobile diagnostic device can be removed from the self-blast circuit breaker after performing the method and mounted on a further self-blast circuit breaker for renewed performance of the method. Thus, for a plurality of self-blast circuit breakers, during the maintenance of the corresponding self-blast circuit breakers, in each case the state of the burn-off nozzle can be determined.

While exemplary embodiments have been described with reference to the figures, modifications can be carried out in further exemplary embodiments.

For example, the methods and mobile diagnostic devices can also be used when a plurality of self-blast circuit breakers are combined in an arrangement or “battery” of self-blast circuit breakers which has a common filling port and/or a common drive shaft. In this case, the different circuit breakers are switched into the open state in parallel by the drive shaft. The transient pressure profile respectively measured at the filling port as measuring position can be evaluated in order to determine the state of the burn-off nozzle for each of the plurality of self-blast circuit breakers.

Further sensors can be used to perform the diagnosis of the self-blast circuit breaker. For example, a resistance, voltage drop or current between the contacts of the self-blast circuit breaker can be measured to determine the time at which the contact separation takes place. In dependence on the time thus determined, a recording of the pressure profile which is detected at the measuring position can be triggered and/or a time interval, for which the detected pressure profile is further evaluated, can be set.

While the diagnosis can be performed such that it is only determined whether the self-blast circuit breaker is to be disassembled and the housing opened for an inspection of the burn-off nozzle, the diagnosis can also quantitatively determine the state of the burn-off nozzle. For example, the transient pressure profile which is detected in the diagnosis at the measuring position can also be evaluated in order to quantitatively determine the nozzle burn-off therefrom. For this purpose, a comparison can be made with characteristic diagrams or other tables, in which for the respective construction type of the self-blast circuit breaker the resulting pressure profiles in dependence on the nozzle burn-off are stored.

With the aid of methods and diagnostic devices according to exemplary embodiments, the state of the burn-off nozzle of a self-blast circuit breaker can be determined non-invasively in the course of a maintenance on the self-blast circuit breaker. A time- and cost-intensive opening of the housing of the self-blast circuit breaker in a workshop can thus be avoided. The methods and diagnostic devices provide a means with which the life expectancy or time until the next inspection of a self-blast circuit breaker can be reliably determined and thereby an efficient use of the self-blast circuit breaker in the electrical energy supply network ensured.

Self-blast circuit breakers are widely used today in the electrical energy supply networks of the high- and extra-high-voltage level. Exemplary embodiments of the invention can thus support the maintenance and servicing strategy of energy suppliers or network operators.

1. A method of diagnosing a self-blast circuit breaker, the method comprising:
triggering a switching operation of the self-blast circuit breaker (1) to initiate a pressure wave in a filling gas of the self-blast circuit breaker,
detecting a pressure as a function of time in at least one region of the self-blast circuit breaker in response to the switching operation, and
determining a state of a burn-off nozzle of the self-blast circuit breaker which is burnt off in a switching operation under load for blowing the filling gas onto a switching arc, the state of the burn-off nozzle being determined in dependence on the pressure as a function of time.

2. The method of claim 1,
wherein the state of the burn-off nozzle is determined based on a transient pressure variation in the pressure as a function of time, which is detected in response to the switching operation in a time interval.

3. The method of claim 2,
wherein the pressure as a function of time is detected at a filling port of the self-blast circuit breaker for refilling the filling gas, which is spaced from the burn-off nozzle.

4. The method of claim 2, the method further comprising:
detecting a contact separation of contacts of the self-blast circuit breaker,
the time interval being set in dependence on a time at which the contact separation takes place.

5. The method of claim 4,
wherein a mechanical drive of the self-blast circuit breaker and/or an electric connection of the contacts of the self-blast circuit breaker is monitored to detect the contact separation.

6. The method of claim 2, the method further comprising:
detecting a pressure and a temperature of the filling gas before the switching operation is triggered,
the time interval being set in dependence on the pressure and the temperature of the filling gas detected prior to triggering the switching operation.

7. The method of claim 6,
the time interval being set further in dependence on a geometry of the self-blast circuit breaker.

8. The method of claim 2,
wherein the state of the burn-off nozzle is determined in dependence on a time integral of the detected transient pressure variation.

9. The method of claim 1,
wherein the state of the burn-off nozzle is determined in dependence on at least one spectral component of the detected pressure as a function of time.

10. The method of claim 1, the method further comprising:
receiving a user input with information associated with the self-blast circuit breaker,
wherein the state of the burn-off nozzle is determined in dependence on the pressure as a function of time and in dependence on a database query which is performed based on the user input.

11. The method of claim 1,
wherein the determined state of the burn-off nozzle is selected from a first state, which allows operation of the self-blast circuit breaker to be continued, and a second state, which requires a visual inspection of the burn-off nozzle of the self-blast circuit breaker.

12. A diagnostic device for a self-blast circuit breaker, comprising:
an interface for receiving pressure data which indicate a pressure as a function of time in at least one region of the self-blast circuit breaker in response to a switching operation of the self-blast circuit breaker, and
a control coupled to the interface and configured to determine, in dependence on the pressure data, a state of a blow-off nozzle of the self-blast circuit breaker which is burnt off in a switching operation under load.

13. The diagnostic device of claim 12, further comprising:
a pressure sensor configured to be coupled to the interface, the pressure sensor having a coupling structure configured for mounting to a filling port of the self-blast circuit breaker.

14. The diagnostic device of claim 12, further comprising:
a rotation angle sensor for detecting a rotation angle of a drive shaft of the self-blast circuit breaker,
the control being coupled to the rotation angle sensor and being configured to determine the state of the burn-off nozzle in dependence on a pressure variation in a time interval which is a function of the detected rotation angle.

15. (canceled)

16. The diagnostic device of claim 12,
wherein the control is configured to determine the state of the burn-off nozzle based on a transient pressure variation in the pressure as a function of time indicated by the pressure data, the transient pressure variation occurring in response to the switching operation in a time interval.

17. The diagnostic device of claim 16,
wherein the diagnostic device is configured to detect the pressure as a function of time at a filling port of the self-blast circuit breaker for refilling the filling gas, which is spaced from the burn-off nozzle.

18. The diagnostic device of claim 16,
the time interval being set in dependence on a time at which a contact separation of contacts of the self-blast circuit breaker takes place.

19. The diagnostic device of claim 16,
the time interval being set in dependence on a pressure and a temperature of the filling gas detected prior to triggering the switching operation.

20. The diagnostic device of claim 12,
wherein the control is configured to determine the state of the burn-off nozzle in dependence on a time integral of the detected transient pressure variation.
